(19) United States
(12) Patent Application Publication
(10) Pub. No.: US 2006/0179378 A1
(43) Pub. Date: Aug. 10, 2006

(54) Semiconductor integrated circuit and method of testing the same

(75) Inventors: Masahisa Iida, Takatsuki-shi (JP); Yuji Yamasaki, Mishima-gun (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/338,684

(22) Filed: Jan. 25, 2006

(30) Foreign Application Priority Data
Jan. 27, 2005 (JP) 2005-019887

(51) Int. Cl. G01R 31/28

(52) U.S. Cl. 714/733

(57) ABSTRACT

In this semiconductor integrated circuit, outputs of a fuse for power supply level adjustment and an internal register are selectively switched by a selector, and a selected output is inputted to a reference voltage generating circuit. Hence, the same reference voltage can be generated before and after blowing the fuse. An internal power supply voltage is generated based on this reference voltage. That makes it possible to output the same internal power supply voltage as that after blowing the fuse by using the output of the internal register before blowing the fuse. As the result of this, a redundant relief determination test using the internal power supply can be performed, and by executing a test at the same speed as that of an actual operation using BIST, an error between the internal voltages during a test and during an actual operation can be eliminated, thus achieving a highly accurate redundant relief determination of a marginal bit.

### BACKGROUND OF THE INVENTION

1. Field of the Invention

The present invention relates to a semiconductor integrated circuit (semiconductor memory device) and a method of testing the same. Particularly, this semiconductor integrated circuit is configured of an embedded memory and a circuit for testing the same.

2. Description of the Related Art

In recent years, both of high integration for achieving SOC (System On Chip) at a low cost, and high-speed random operation capability have been required particularly for an embedded DRAM. Meanwhile, to secure an operation margin has been significantly difficult.

In a DRAM, electric charges that stored in a memory cell capacitor are read as a difference voltage (a read voltage) between a read bit line and a reference bit line to thereby amplify the read voltage by a sense amplifier, so that information “0” and “1” are read. A decrease in this read voltage of the DRAM causes a difficulty for the operation margin to be secured.

One of the major causes of the decrease in the read voltage is a decrease in capacity of the cell capacitor. This is because, in the case of the so-called stacked type capacitor, while a size in two-dimensional directions of the capacitor is reduced with the progress of microfabrication, a size in a height direction thereof is also reduced by a drop of an exposure margin (defocus margin). While countermeasures of introducing a high dielectric constant insulating film into the capacitor or the like are taken, the capacity of the capacitor, which has conventionally been 30 fF or more, is rapidly reduced to a degree of several fFs.

In addition to that, a decrease in DRAM supply voltage is also a cause of reducing the read voltage. This is because, in order to achieve a low cost, a current embedded DRAM results in the so-called logic compatible process that may be achieved by means of a minimum process addition to a normal standard CMOS process, so that, in a DRAM portion other than a memory cell transistor, the same transistor as that of a logic portion is required to be used. In other words, with the progress of microfabrication, in accordance with a rapid decrease in supply voltage to the transistor of the logic portion, a supply voltage of the DRAM portion has also been decreased rapidly.

Meanwhile, DRAM has many internal voltages. For example, a bit line precharge voltage VBP, a cell plate voltage VCP, and a substrate voltage VBB may be included. Voltages, such as a DRAM main voltage VDD and a word line boot voltage VPP may further be internally generated.

The power supply voltages that are internally generated may be varied due to process variability. For that reason, a semiconductor device is generally shipped after voltage levels are adjusted for every chip by means of fuse trimming. Meanwhile, high accuracy is required for setting accuracy of the internal power supply voltage. Taking an example of the bit line precharge voltage VBP serving as a reference voltage of the bit line read voltage, setting accuracy of at least 10 mV order will be required particularly for a future embedded DRAM in which a small read voltage will be used.

FIG. 13 shows an example of a test circuit configuration in which an internal voltage is applied from an external tester to thereby perform a redundant relief determination. Here, the bit line precharge voltage VBP is shown as an exemplary example.

Conventionally, in order to reduce a test man-hour, blowing a fuse for power supply adjustment and a fuse for redundant relief has been collectively performed after the redundant relief determination. For that reason, an internal voltage output during the redundant relief determination could not be set to a value after the adjustment by the fuse. Hence, a redundant relief determination test in which the internal voltage after the adjustment by blowing the fuse (to be assumed) has been applied from an external source has typically been performed.

In FIG. 13, reference numeral 2001 represents a memory tester; reference numeral 2002, a DRAM macro; reference numeral 2003, an internal voltage power supply; reference numeral 2004, a memory control circuit; reference numeral 2005, a memory array; reference numeral 2006, a SRAM macro; and reference numeral 2007, a logic circuit. Symbol VBP represents a bit line precharge voltage, symbol VDD represents a DRAM main voltage, and symbol VSS represents a ground voltage.

Moreover, reference numeral 1 represents a driver; reference numeral 2, an amplifier; reference numeral 3, a programmable reference voltage generating circuit; reference numeral 4, a fuse; reference numeral 5, a sequencer for providing a test pattern to the DRAM macro 1002; reference numeral 6, a redundant determining circuit for receiving read data from the DRAM macro 1002; and reference numeral 7, a power supply circuit whose voltage is variable. Symbol R represents a parasitic resistance and symbol L represents a parasitic inductance.

A conventional test flow is shown in FIG. 14. In the conventional test flow, a wafer test and a package test have been performed to an embedded memory (DRAM) and a logic circuit in the order using different testers, respectively. In the wafer test, a DRAM test is performed using a memory tester and a logic test is performed using a logic tester. Meanwhile, in the package test, the memory test is performed using the memory tester and the logic test is performed using the logic tester.

In the wafer test, by extracting fuse blowing information according to a predetermined table based on an output voltage monitored in a DC internal power supply test that is performed before a function test, the internal power supply voltage is adjusted so as to be coincident with a target voltage (determination of power supply adjustment connection fuse). It should be noted that as for the DC internal power supply test, a contact and current test is performed before monitoring the internal power supply voltage. Incidentally, the function test here is a test for redundant relief at a frequency lower than that of an actual operation.

Moreover, in the function (redundant relief determination) test, a voltage, which is predicted to be outputted after adjustments by fuse trimming, is applied from the external source (memory tester) as the internal voltage to perform a PASS/FAIL test. The redundant relief determination to the worst bit is thereby performed. Hence, a redundant relief row and column (=blowing fuse) will be determined. Moreover, this function test is usually performed at the frequency (memory tester performance determines the rate) lower than that of an actual operation. Needless to say, if an expensive memory tester corresponding to a high-speed testing is used, the test may be performed at the same frequency as that of an actual operating speed. When considering that, an improvement in speed of the embedded memory and an increase in the number of mounted macros will further be advanced in the future, and an increase in a test cost with respect to a chip cost will also be remarkable due to a scaling rule, however, that approach may be unrealistic.

In order to secure the operation margin in the situation where the read voltage is decreased, it is desirable that the redundant relief is highly accurately performed by means of adjusting an internal power supply voltage level during the redundant relief determination of a marginal bit that is easy to receive an effect of a fluctuation of the internal voltage, into the same as the internal voltage generating level during an actual operation.

Patent Document 1: Japanese Patent No. 3014420

Patent Document 2: Japanese Unexamined Patent Publication (Kokai) No. 2001-35199

Patent Document 3: Japanese Unexamined Patent Publication (Kokai) No. H8-315598

In the conventional configuration, however, by applying the internal power supply voltage from the outside to thereby perform the redundant relief determination test as shown in FIG. 15, there arises a problem that an internal voltage in determining the worst bit is different from a voltage in generating the voltage by the internal power supply during an actual operation.

Based on the inventor's experience, in the worst case, this voltage error easily exceeds 100 mV in a power supply for generating the aforementioned bit line precharge voltage VBP. As a result, particularly in the future microfabrication DRAM, which may have a small read voltage, and in which an improvement in speed of an actual operation frequency will be proceeded, there arises a problem that the operation margin of the marginal bit may not be sufficiently secured.

As can be seen, in FIG. 15, the bit line precharge voltage VBP and the ground voltage VSS during a test in the outside (tester) output portion, the bit line precharge voltage VBP and the ground voltage VSS during a test in the inside (chip), and the bit line precharge voltage VBP and the ground voltage VSS during an actual operation are shown. In FIG. 15, for example, in the inside (chip), there is shown in that, there is a voltage error between the bit line precharge voltage VBP during a test, and the bit line precharge voltage VBP during an actual operation, and operation frequencies are different between the bit line precharge voltage VBP and the ground voltage VSS during a test, and the bit line precharge voltage VBP and the ground voltage VSS during an actual operation, respectively.

The error between the internal voltage during this redundant relief determination and the internal voltage during an actual operation will be caused by following reasons.

(A) AC power supply load characteristics are different,

(B) transient response characteristics of driving power supplies are different (power supplies themselves are different).

Following reasons may be considered as the cause that the AC load characteristics are different described in (A).

1) When the internal power supply voltage is externally applied, loads such as a parasitic resistance, a parasitic inductance, or the like due to a test board, a pin, an interconnection from the pin to the DRAM macro, or the like, which may not be added during an actual operation, are added,

2) as is shown in the drawing, although the operation frequencies are different during a test and during an actual operation, since a load current characteristic within the memory itself has a frequency characteristic, the loads are different during a test and during an actual operation,

3) when a plurality of memory macros are incorporated, a load current characteristic changes due to the number of macros which are simultaneously operating, and

4) noises of power supply lines for supplying the DRAM main voltage VDD, the ground voltage VSS, or the like are different during a test and during an actual operation.

Hence, a reference voltage level will be shifted from a desired value, or a response characteristic of the amplifier or the like will be influenced.

These are caused by following reasons.

4a) In a semiconductor integrated circuit composed of a plurality of DRAM macros, the numbers of macros which simultaneously operate are different during a test and during an actual operation.

4b) Normally, in SOC, the SRAM macro is formed on the same semiconductor substrate as DRAM, but the numbers of SRAM macros which simultaneously operate are different during a DRAM test and during an actual operation.

4c) Activation rates of the logic circuit formed on the same semiconductor substrate as DRAM using SOC are different during a DRAM test and during an actual operation. For example, during a DRAM test using the memory tester, the logic circuit has not been normally activated.

In order to solve these problems and the internal power supply voltages during a test and during an actual operation are made the same, firstly, it is necessary to perform the redundant relief of the marginal bit using an internal power supply as the internal voltage output level after being adjusted by the fuse, and by a test at the same speed as that of an actual operation.

Japanese Patent Publication No. 3014420 describes a power supply adjustment method which can pseudoly adjust the internal power supply voltage output into a value after blowing the fuse. However, the object is primarily generating an acceleration voltage using the internal power supply during a burn-in test whose speed is normally slower than that of an actual operating, so that it does not provide means for allowing a test with the same speed as that of an actual operation.

Moreover, Japanese Unexamined Patent Publication (Kokai) No. 2001-35199 does not have means for allowing the test with the same speed as that that of an actual operation, either, and the object is different from that of the present invention.

Further, Japanese Unexamined Patent Publication (Kokai) No. H8-315598 describes a BIST (Built In Self Test) circuit which has a power supply marginal test function. Although the internal power supply level can be changed using BIST, the object is not to make the internal voltage levels during a test and during an actual operation the same, but it is assumed to apply a voltage higher than a normal voltage because of an accelerated test, so that it is not provided with means for matching the internal voltage levels during a test and during an actual operation, either.

Finally, there are no well-known technologies on the configuration in which BIST is utilized for the accurate setting of the internal power supply level and for the improvement in redundant relief accuracy, and methods of testing the same. Further, as for an accurate setting of the internal power supply level by taking into considerations of even the effect of the aforementioned reasons 1), 2), 3), and 4), and a configuration and a test method utilizing it for an improvement in redundant relief accuracy, there has no solution means, as a matter of course.

Moreover, in the conventional test flow shown in FIG. 14, according to a predetermined table based on the voltage which is monitored in the DC internal power supply test performed before the function test, the internal power supply voltage is adjusted to a predetermined target voltage. This target voltage itself, however, is defined by a statistical analysis from a certain limited evaluation result. In other words, there is also a problem that the target voltage itself is not assured that it is a voltage for maximizing the operation margin for the respective memory macros of each actual chip.

Although the power supply that generates the bit line precharge voltage VBP of DRAM has been described as the example so far, it is needless to say that the power supplies for generating the aforementioned cell plate voltage VCP, substrate voltage VBB, DRAM main voltage VDD, and word line boot voltage VPP may also have a problem similar to that described above.

Moreover, as for SRAM, the internal power supply is not normally provided at present, but an increase in leakage current and a decrease in static noise margin will become a problem with future microfabrication. For these countermeasures, for example, a power supply for substrate bias of an array portion, and a power supply for word line and bit line boot may be used. However, the problems that it is required to accurately set the internal power supply voltage of these SRAMs to thereby achieve a highly accurate redundant relief will be the same as those of DRAM.

### SUMMARY OF THE INVENTION

The present invention aims at highly accurately relieving a marginal bit which rate-controls an operation margin, by reducing an error between an internal voltage during a function test and an internal voltage during an actual operation, which has been the problem described above, and also by performing a redundant relief determination test which simulates an actual SOC operating state.

Moreover, the present invention aims at allowing the internal power supply voltage itself to be set to a voltage for maximizing the operation margin for every individual macro, and further allowing the number of test processes to be reduced (reduction in test cost).

A semiconductor integrated circuit according to a first aspect of the present invention includes
at least one dynamic RAM including a first memory cell array composed of a plurality of memory cells, and a first internal voltage generating circuit for generating a first internal voltage based on a reference voltage,
first non-volatile reference voltage memory means for non-volatilely storing a first reference voltage setting data which sets a reference voltage of the at least one dynamic RAM, and outputting the first reference voltage setting data,
first volatile reference voltage memory means for volatilely storing a second reference voltage setting data which sets a reference voltage of the at least one dynamic RAM, and outputting the second reference voltage setting data,
a first selector for selecting and outputting either of an output of the first non-volatile reference voltage memory means, and an output of the first volatile reference voltage memory means, and
first reference voltage generating means for generating a reference voltage of the at least one dynamic RAM based on an output of the first selector to input it to the first internal voltage generating circuit, and
first built-in memory test means including a sequencer portion for generating a test signal including a write/read address and a write-in data, and at least one result-determining portions for determining a test result by comparing the test signal from the sequencer portion with data contents read from the at least one dynamic RAM.

By applying a test method of a second aspect of the present invention to a configuration of the aforementioned first aspect of the present invention, a voltage level of the first internal voltage generating circuit can be set to a value after a voltage adjustment, and a function test can be executed at the same operating speed as that of an actual chip by using the first built-in memory test means. For that reason, a redundant relief determination is made at the completely same internal voltage level as that during an actual operation, so that correct relief of a marginal bit can be achieved against a small fluctuation in the internal voltage level.

In the configuration of the aforementioned first aspect of the present invention, preferably, the first built-in memory test means has voltage tuning means for individually changing a value of the second reference voltage setting data to be written in the first volatile reference voltage memory means in the at least one dynamic RAM to thereby tune so that a reference voltage supplied from an external terminal and the first internal voltage may be the same voltage, respectively.

According to this configuration, without being rate-controlled by the number of DC voltage monitor channels of the tester even when the number of built-in macros is increased, by writing the same or different binary data in a plurality of first volatile reference voltage memory means, all of the internal power supply voltages of a plurality of macros can be easily set to the same voltage.

In addition, in the configuration of the aforementioned first aspect of the present invention, preferably, the first built-in memory test means has memory means for the first reference voltage setting data to be written in the first non-volatile reference voltage memory means, and redundant relief determination means for the at least one dynamic RAM. Moreover, in the configuration of the aforementioned first aspect of the present invention, preferably, the first non-volatile reference voltage memory means is an electrical fuse.

By employing this configuration, accurate level setting of the first internal voltage, redundant relief determination, and blowing fuses for redundant relief and for power supply adjustment can be made possible only by the logic tester without using the memory tester, thus allowing a high accurate test and redundant relief determination to be achieved in a short time, namely at a low cost.

Moreover, in the configuration of the aforementioned first aspect of the present invention, preferably, the first internal voltage is a bit line precharge voltage.

According to this configuration, bit line precharge levels which are very sensitive to read characteristics of the cell, namely, the minimum operating voltage can be highly accurately set to the same level during a screening and during an actual operation. That makes it possible to reliably relieve the worst bit, and secure the operation margin.

In addition, in the configuration of the aforementioned first aspect of the present invention, preferably, the first internal voltage is a cell plate voltage.

According to this configuration, a tunnel leakage current, which has been particularly remarkable in high dielectric capacitor insulating film materials in recent years, and which is largely dependent on an applied voltage of a capacitor insulating film can be minimized by a screening due to a highly accurate cell plate voltage setting, thus allowing an electric charge holding time to be maximized.

In addition, in the configuration of the aforementioned first aspect of the present invention, preferably, the first internal voltage is a substrate bias voltage of the first memory cell array.

According to this configuration, a channel leak and a junction leak of the memory cell transistor can be minimized by a screening due to a highly accurate substrate bias voltage setting, thus allowing an electric charge holding time to be maximized.

In addition, in the configuration of the aforementioned first aspect of the present invention, preferably, the first internal voltage is a main power supply voltage of the at least one dynamic RAM.

Particularly, when a redundant determination has been made by applying the DRAM main power supply voltage, which has a high current consumption and a frequency dependence, from an external source as before, it has been largely influenced by an inductance and a ground noise due to an interconnection on a board or the like, so that there has been a possibility that the voltage level during a screening has been significantly shifted from that during an actual operation. By employing the configuration according to the present invention, however, the main power supply voltage levels during a screening and during an actual operation can be made the same. That makes it possible to perform the high accurate screening, and secure the operation margin.

In addition, in the configuration of the aforementioned first aspect of the present invention, preferably, the first internal voltage is a word line voltage.

While the word line voltage during an actual operation is varied in AC because of being generated by a charge pump, when the external voltage has applied as the conventional test method, a screening to which even this AC fluctuation has been reflected has been impossible. By employing the configuration according to the present invention, however, the voltage levels of the word line during a screening and during an actual operation can be made the same. That makes it possible to perform the high accurate screening, and secure the operation margin.

In addition, in the configuration of the aforementioned first aspect of the present invention, at least one static RAM, second built-in memory test means for testing the at least one static RAM, and a logic circuit may further be provided.

By employing this configuration, in a state where the at least one dynamic RAM, the at least one static RAM, and the logic circuit are simultaneously activated by the test mode setting from the logic tester, a redundant relief determination on conditions closer to actual operating conditions of SOC where a noise that wrap-arounds therefrom via a power supply line and a ground line influences is made. Hence, correct relief of a marginal bit can be achieved against a small fluctuation in the internal voltage level. Moreover, a reduction in test time due to a simultaneous test can also be achieved.

As described above, in the case of the semiconductor integrated circuit provided with the at least one static RAM and the second built-in memory test means, preferably, the second built-in memory test means is controlled by an output signal from the first built-in memory test means to thereby activate the at least one static RAM.

According to this configuration, the at least one static RAM can be activated without using the logic tester, allowing a highly accurate redundant relief determination to be achieved easily.

Moreover, in the case of the semiconductor integrated circuit provided with the at least one static RAM and the second built-in memory test means as described above, preferably,
the at least one static RAM includes a second memory cell array composed of a plurality of memory cells, and a second internal voltage generating circuit for generating a second internal voltage based on a reference voltage, and
the semiconductor integrated circuit further includes
second non-volatile reference voltage memory means for non-volatilely storing a third reference voltage setting data which sets a reference voltage of the at least one static RAM, and outputting the third reference voltage setting data,
second volatile reference voltage memory means for volatilely storing a fourth reference voltage setting data which sets a reference voltage of the at least one static RAM, and outputting the fourth reference voltage setting data,
a second selector for selecting and outputting either of an output of the second non-volatile reference voltage memory means, and an output of the second volatile reference voltage memory means, and
second reference voltage generating means for generating a reference voltage of the at least one static RAM based on an output of the second selector to input it to the second internal voltage generating circuit.

By employing this configuration, a redundant relief determination of accurately adjusting voltage levels of the internal power supplies of at least one static RAM, which will be required for future microfabrication processes, can be made, and correct relief of the marginal bit of the at least one static RAM can also be achieved.

In the configuration described above, preferably, the second internal voltage is a substrate bias voltage, a power supply voltage of a word line or a bit line of the second memory cell array.

By employing this configuration, it is possible to accurately adjust a substrate bias voltage and a bit line boot voltage of a memory array portion used for a reduction in power of a micro-fabricated static RAM, into a bias at which the speed, minimum of operation, and leakage current become optimal.

A test method of a semiconductor integrated circuit according to a second aspect of the present invention is a test method of testing the semiconductor integrated circuit described in the first aspect of the present invention, wherein a function test of the dynamic RAM is performed at a first internal voltage generated based on the second reference voltage data which is volatilely stored in the first volatile reference voltage memory means, and at the same operating speed as that of an actual chip.

By applying this test method to the semiconductor integrated circuit, while the voltage level of the first internal voltage generating circuit can be set to a value after a voltage adjustment, the function test can be executed at the same operating speed as that of an actual chip by using the first built-in memory test means. For that reason, a redundant relief determination is made at the completely same internal voltage level as that during an actual operation, so that correct relief of a marginal bit can be achieved against a small fluctuation in the internal voltage level.

In the configuration of the aforementioned second aspect of the present invention, preferably, the at least one dynamic RAM includes a plurality of dynamic RAMs, and the function test of the plurality of dynamic RAMs is performed in a state where all of the plurality of dynamic RAMs are activated.

According to this test method, a redundant relief determination is made under the conditions where a noise that wrap-arounds from a peripheral dynamic RAM via the power supply line and the ground line influences most largely. Hence, correct relief of a marginal bit can be achieved against a small fluctuation in the internal voltage level. Moreover, a reduction in test time due to simultaneous tests can also be achieved.

Moreover, in the configuration of the aforementioned second aspect of the present invention, preferably, the second reference voltage setting data written in the first volatile reference voltage memory means during a function test, and the first reference voltage setting data written in the first non-volatile reference voltage memory means after the function test are the same.

According to this test method, the internal power supply voltage levels during a function test and during an actual operation can be set to completely the same level. For that reason, the operation margin of the marginal bit can be secured.

Moreover, in the configuration of the aforementioned second aspect of the present invention, preferably, by writing a plurality of different second reference voltage setting data in the first volatile reference voltage memory means, the function test is performed at a plurality of first internal voltage levels, and after the function test, any second reference voltage setting data among the plurality of different second reference voltage setting data is written in the non-volatile memory means as the first reference voltage setting data.

According to this test method, from a result of the redundant relief determination at the plurality of first internal voltage levels, the first internal voltage can be adjusted so that a minimum operating voltage and the number of fail bits may be minimized. For that reason, the operation margin of the marginal bit can be maximized. In addition, in order to select an internal voltage value at which the operation margin actually become maximum, a test process of monitoring a DC level in advance to thereby adjust it into a target voltage that is assumed in advance becomes unnecessary, so that a reduction in test man-hour can be achieved, or an internal voltage monitor terminal and a circuit can be unnecessary.

Moreover, in the configuration of the aforementioned second aspect of the present invention, similar to the first aspect of the present invention, preferably, the first internal voltage is any of a bit line precharge voltage, a cell plate voltage, a substrate bias voltage of the first memory cell array, a main power supply voltage of the at least one dynamic RAM, and a word line voltage.

In addition, when the semiconductor integrated circuit provided with the at least one static RAM and the second built-in memory test means is tested as described above, a function test of the dynamic RAM is preferably performed in a state where all of the plurality of static RAMs are activated, a state where the logic circuit is activated, or a state where the plurality of static RAMs and the logic circuit are simultaneously activated.

According to this test method, the dynamic RAM, the static RAM, and the logic circuit are simultaneously activated, and a redundant relief determination on conditions where a noise that wrap-arounds therefrom via the power supply line and the ground line becomes the worst is made. Hence, correct relief of a marginal bit can be achieved against a small fluctuation in the internal voltage level.

A semiconductor integrated circuit according to a third aspect of the present invention includes at least one dynamic RAM including a first memory cell array composed of a plurality of memory cells, and a first internal voltage generating circuit for generating a first internal voltage based on a reference voltage,
a first electrical fuse for non-volatilely storing first reference voltage setting data which sets a reference voltage of the at least one dynamic RAM, and outputting the first reference voltage setting data,
first reference voltage generating means for generating a reference voltage of the at least one dynamic RAM based on an output of the first electrical fuse to input it to the first internal voltage generating circuit, and
first built-in memory test means including a sequencer portion for generating a test signal including a write/read address and a write-in data, and at least one of result-determining portions for determining a test result by comparing the test signal from the sequencer portion with data contents read from the at least one dynamic RAM.

According to this configuration, without using the volatile reference voltage memory means, a highly accurate redundant relief determination can be made.

Moreover, in the configuration of the aforementioned third aspect of the present invention, similar to the first aspect of the present invention, preferably, the first internal voltage is any of a bit line precharge voltage, a cell plate voltage, a substrate bias voltage of the first memory cell array, a main power supply voltage of the at least one dynamic RAM, and a word line voltage.

Moreover, in the configuration of the aforementioned third aspect of the present invention, preferably, the semiconductor integrated circuit further includes at least one static RAM, second built-in memory test means for testing the at least one static RAM, and a logic circuit.

By employing this configuration, in a state where the at least one dynamic RAM, the at least one static RAM, and the logic circuit are simultaneously activated by the test mode setting from the logic tester, a redundant relief determination on conditions closer to actual operating conditions of SOC where a noise that wrap-arounds therefrom via the power supply line and the ground line influences is made. Hence, correct relief of a marginal bit can be achieved against a small fluctuation in the internal voltage level. Moreover, a reduction in test time due to a simultaneous test can also be achieved.

As described above, in the semiconductor integrated circuit provided with the at least one static RAM and the second built-in memory test means, preferably, the second built-in memory test means is controlled by an output signal from the first built-in memory test means to thereby activate the at least one static RAM.

According to this configuration, the at least one static RAM can be activated without using the logic tester, so that a highly accurate redundant relief determination can be achieved easily.

Moreover, in the semiconductor integrated circuit provided with the at least one static RAM and the second built-in memory test means as described above, preferably,
the at least one static RAM includes a second memory cell array composed of a plurality of memory cells, and a second internal voltage generating circuit for generating a second internal voltage based on a reference voltage, and
the semiconductor integrated circuit further including
a second electrical fuse for non-volatilely storing second reference voltage setting data which sets a of the at least one static RAM, and outputting the second reference voltage setting data, and
second reference voltage generating means for generating a reference voltage of the at least one static RAM based on an output of the second electrical fuse to input it to the second internal voltage generating circuit.

By employing this configuration, a redundant relief determination of accurately adjusting voltage levels of the internal power supplies of the at least one static RAM, which will be required for future microfabrication processes, can be made, and correct relief of the marginal bit of the at least one static RAM can also be achieved.

In the aforementioned configuration, preferably, the second internal voltage is a substrate bias voltage, a power supply voltage of a word line or a bit line of the second memory cell array.

By employing this configuration, it is possible to accurately adjust a substrate bias voltage and a bit line boot voltage of a memory array portion used for a reduction in power of a micro-fabricated static RAM, into a bias at which the speed, minimum of operation, and leakage current become optimal.

A test method of a semiconductor integrated circuit according to a fourth aspect of the present invention is a test method of testing the semiconductor integrated circuit described in the third aspect of the present invention, wherein after blowing an electrical fuse for non-volatilely storing the reference voltage setting data, a redundant repair determination test is performed.

By employing this method, a reduction in test man-hour for once pseudoly generating the internal voltage after fuse trimming, using the volatile reference voltage memory means can be achieved, and a highly accurate redundant repair determination can be made.

Moreover, in the configuration of the aforementioned fourth aspect of the present invention, similar to the first aspect of the present invention, preferably, the first internal voltage is any of a bit line precharge voltage, a cell plate voltage, a substrate bias voltage of the first memory cell array, a main power supply voltage of the at least one dynamic RAM, and a word line voltage.

Moreover, when the semiconductor integrated circuit provided with the plurality of static RAMs and the second built-in memory test means is tested as described above, a function test of the dynamic RAM is preferably performed in a state where all of the plurality of static RAMs are activated, a state where the logic circuit is activated, or a state where the plurality of static RAMs and the logic circuit are simultaneously activated.

According to this test method, by simultaneously activating the dynamic RAM, the static RAM, and the logic circuit, a redundant relief determination on conditions where a noise that wrap-arounds therefrom via the power supply line and the ground line becomes the worst is made. Hence, correct relief of a marginal bit can be achieved against a small fluctuation in the internal voltage level.

A semiconductor integrated circuit according to a fifth aspect of the present invention includes
at least one dynamic RAM including a first memory cell array composed of a plurality of memory cells, and a first internal voltage generating circuit for generating a first internal voltage based on a reference voltage,
first non-volatile reference voltage memory means for non-volatilely storing a first reference voltage setting data which sets a reference voltage of the at least one dynamic RAM, and outputting the first reference voltage setting data,
an external terminal which is connected to first voltage control means for outputting second reference voltage setting data which set a reference voltage of the at least one dynamic RAM, and to which the second reference voltage setting data is inputted,
a first selector for selecting and outputting either of an output of the first non-volatile reference voltage memory means, and an input from the external terminal,
first reference voltage generating means for generating a reference voltage of the at least one dynamic RAM based on an output of the first selector to input it to the first internal voltage generating circuit, and
first built-in memory test means including a sequencer portion for generating a test signal including a write/read address and write-in data, and at least one result-determining portions for determining a test result by comparing the test signal from the sequencer portion with data contents read from the at least one dynamic RAM.

According to this configuration, the volatile reference voltage memory means can be eliminated, and the configuration other than that is similar to that of the first aspect of the present invention.

A test method of a semiconductor integrated circuit according to a sixth aspect of the present invention is a test method of testing the semiconductor integrated circuit described in the fifth aspect of the present invention, wherein a function test of the dynamic RAM is performed at a first internal voltage generated based on the second reference voltage setting data which is inputted from the external terminal, and at the same operating speed as that of an actual chip.

According to this method, the same effect as that of the first embodiment of the present invention can be achieved.

As described above, in the conventional test method, since the redundant repair determination test has been performed by applying the internal power supply voltage from the outside, AC-load characteristics of the internal power supply have been different during a screening and during an actual operation, and the response characteristics have been different because of a difference of the power supplies for driving the load. For this reason, correct marginal bit redundant relief has been impossible due to a difference between the internal voltage during a screening and the internal voltage during an actual operation.

However, by applying the present invention, it is possible to perform a screening using the internal power supply voltage and at the same speed as that of an actual operation. For that reason, the operation margin of the marginal bit can be secured due to a highly accurate worst bit relief.

Moreover, a function test with multi-internal voltage levels is performed at the same or different internal voltage levels for every macro, and an internal voltage level providing the maximum operation margin is set as a final internal voltage, so that an increased operation margin can be secured.

Further, by simultaneously operating the dynamic RAM, the static RAM, and the logic circuit during a function test, a redundant relief determination taken into consideration of an effect of a power supply noise during an actual SOC operation can be made, thus allowing the operation margin of the marginal bit to be increased.

It should be noted that this test method could be applied for increasing the operation margin of the embedded memory of not only a dynamic RAM, but also a static RAM provided with the internal power supply or the like.

### BRIEF DESCRIPTION OF THE DRAWINGS

FIG. 1 is a circuit diagram of a semiconductor integrated circuit according to a first embodiment of the present invention;

FIG. 2 is a circuit diagram of a reference voltage generating circuit according to the first embodiment of the present invention;

FIG. 3 is a test flow chart using the semiconductor integrated circuit according to the first embodiment of the present invention;

FIG. 4 is a circuit diagram of a semiconductor integrated circuit according to a second embodiment of the present invention;

FIG. 5 is a test flow chart using the semiconductor integrated circuit according to the second embodiment of the present invention;

FIG. 6 is a circuit diagram of a semiconductor integrated circuit according to a third embodiment of the present invention;

FIG. 7 is a test flow chart using the semiconductor integrated circuit according to the third embodiment of the present invention;

FIG. 8 is a circuit diagram of a semiconductor integrated circuit according to a fourth embodiment of the present invention;

FIG. 9 is a test flow chart using the semiconductor integrated circuit according to the fourth embodiment of the present invention;

FIG. 10 is a circuit diagram of a semiconductor integrated circuit according to a fifth embodiment of the present invention;

FIG. 11 is a test flow chart using the semiconductor integrated circuit according to the fifth embodiment of the present invention;

FIG. 12 is a test flow chart using a semiconductor integrated circuit according to a sixth embodiment of the present invention;

FIG. 13 is a circuit diagram of a semiconductor integrated circuit according to a prior art;

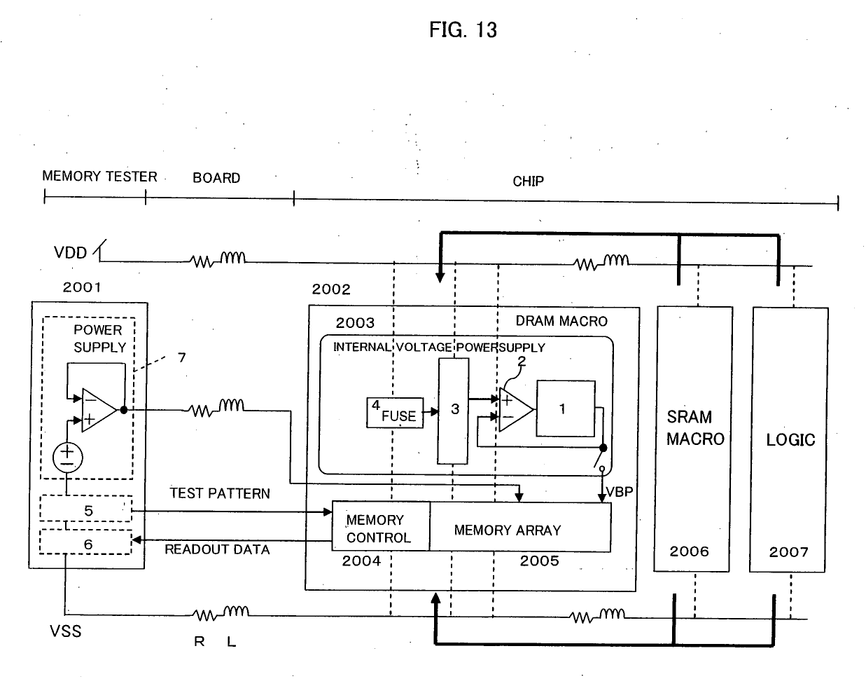

FIG. 14 is a test flow chart using the semiconductor integrated circuit according to the prior art; and

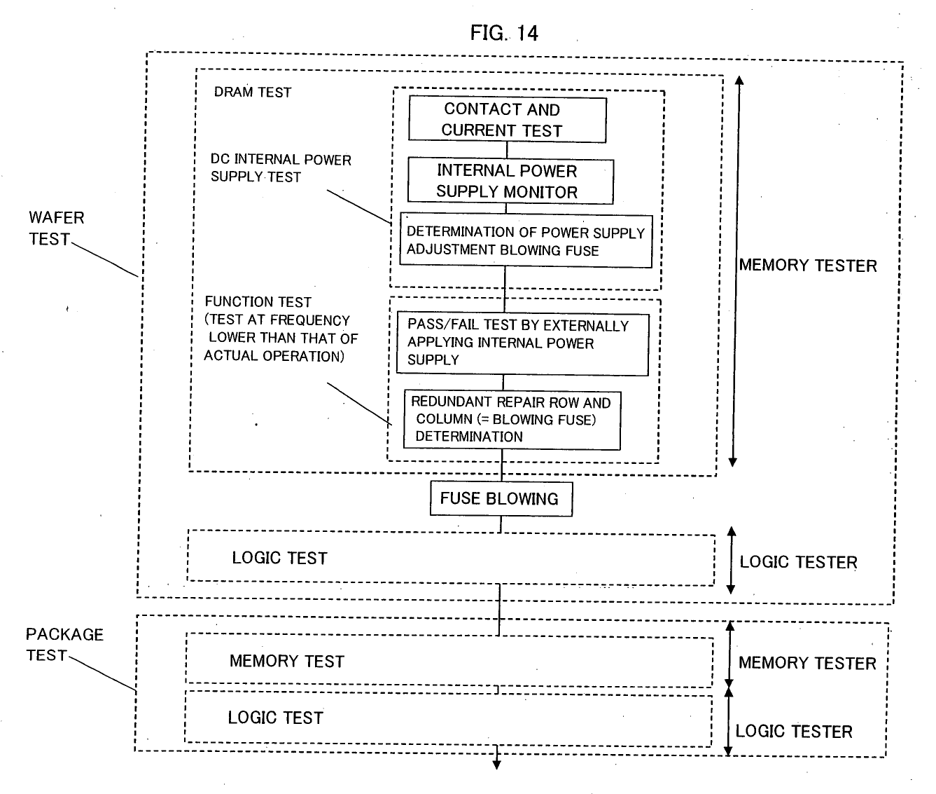

FIG. 15 is a schematic diagram of an internal voltage error according to the prior art.

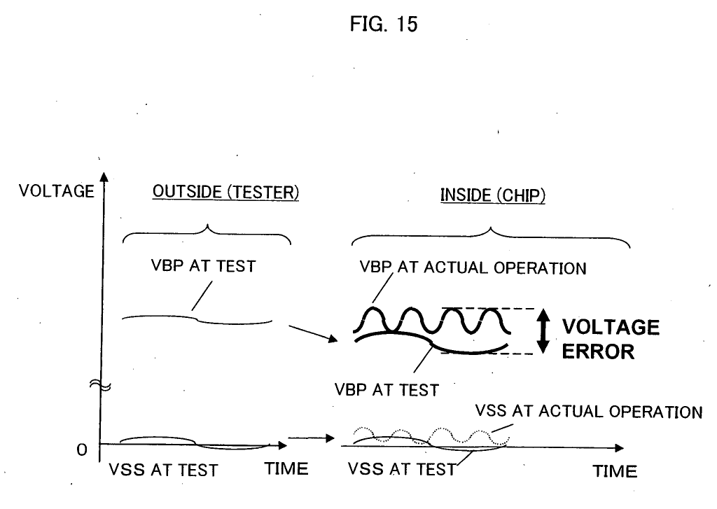

### PREFERRED EMBODIMENT OF THE INVENTION

### First Embodiment

Hereafter, referring to the drawings, a first embodiment of the present invention will be described.

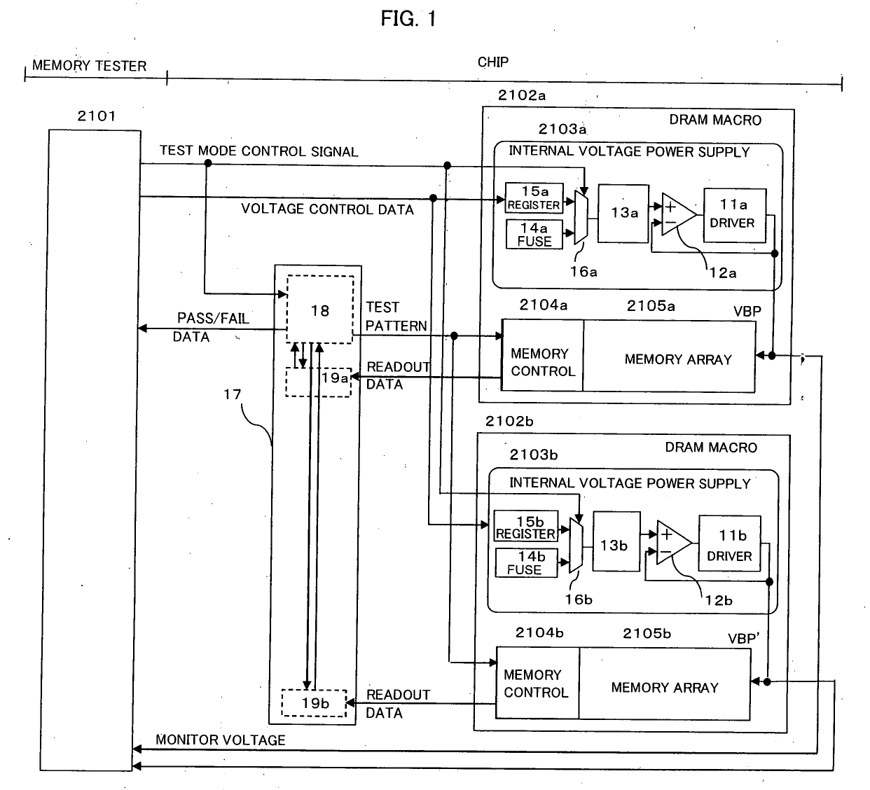

FIG. 1 shows a circuit configuration of a semiconductor memory device according to the first embodiment of the present invention. In FIG. 1, reference numeral 2101 represents a memory tester; reference numerals 2102a and 2102b, DRAM macros; reference numerals 2103a and 2103b, internal voltage power supplies; reference numerals 2104a and 2104b, memory control circuits; and reference numerals 2105a and 2105b, memory arrays. Symbols VBP and VBP′ represent bit line precharge voltages. Reference numerals 11a and 11b represent drivers; reference numeral 12a and 12b, amplifiers; reference numerals 13a and 13b, reference voltage generating circuits; reference numerals 14a and 14b, fuses which are non-volatile reference voltage memory means; reference numerals 15a and 15b, registers which are volatile reference voltage memory means; reference numerals 16a and 16b, selectors; reference numeral 17, a DRAM BIST; reference numeral 18, a sequencer portion; and reference numerals 19a and 19b, read result-determining portions.

The DRAM BIST 17 is generally known and provided with the sequencer portion 18 and the read result-determining portions 19a and 19b. The sequencer portion 18 is composed of a pattern generator, which is not shown in the drawing, for generating a test pattern by a test mode control signal, and a timing generator, which is not shown in the drawing, for generating a memory control signal and a write-in data in response to a signal from the pattern generator. The read result-determining portions 19a and 19b compare expected value data with data read from the memories, and make a pass/fail determination.

Although a test at the same speed as that of an actual operation is achieved by using BIST, the memory tester 2101 is normally used as a tester. It is because that the memory tester 2101 is provided with means for analyzing fail address information of the memory to thereby determine a row and column redundant relief blowing fuse, so that the test is easily performed.

During the test, outputs of the aforementioned registers 15a and 15b are inputted into the aforementioned reference voltage generating circuits 13a and 13b by the test mode control signal, respectively. In the case other than that, outputs of the aforementioned fuses 14a and 14b are inputted into the aforementioned reference voltage generating circuits 13a and 13b, respectively. The output voltages VBP and VBP′ are controlled so as to be the same voltages as the aforementioned reference voltages by the amplifiers 12a and 12b, and the drivers 11a and 11b. Voltage control data is written in the registers 15a and 15b as reference voltage setting data from the memory tester 2101. Meanwhile, the fuses 14a and 14b are blown corresponding to the reference voltage setting data.

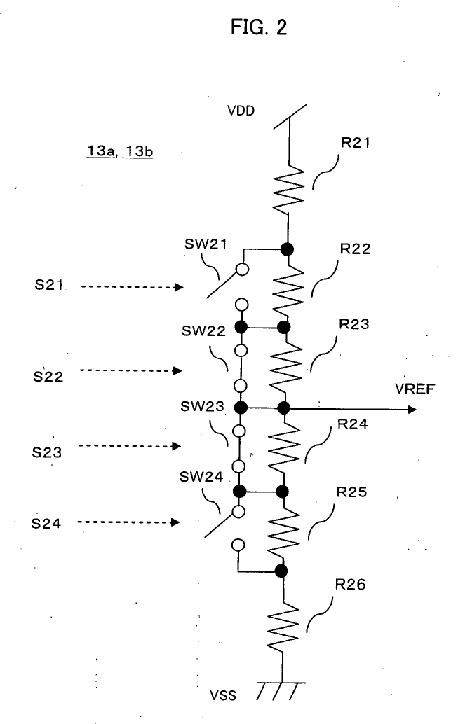

FIG. 2 shows a configuration of the aforementioned reference voltage generating circuits 13a and 13b. In FIG. 2, symbol VDD represents a DRAM main voltage; symbol VSS, a ground voltage; symbol VREF, a reference voltage; symbols R21 through R26, resistors; symbols SW21 through SW24, switches; and symbols S21 through S24, voltage adjustment signals. Here, a transistor may be used as the resistor instead of a resistor element.

By employing this configuration, regardless of from which of the registers 15a and 15b, and the fuses 14a and 14b the voltage adjustment signal (reference voltage setting data) shall be provided, as long as the aforementioned voltage adjustment signals are the same digital signal, the same reference voltage VREF can be outputted. In other words, even before fuse blowing, by inputting the same voltage adjustment signals as those at the time of fuse blowing, from the registers 15a and 15b, reference voltages after fuse blowing are pseudoly generated from the reference voltage generating circuits 13a and 13b, so that the internal power supply voltages after fuse blowing can be pseudoly outputted after all.

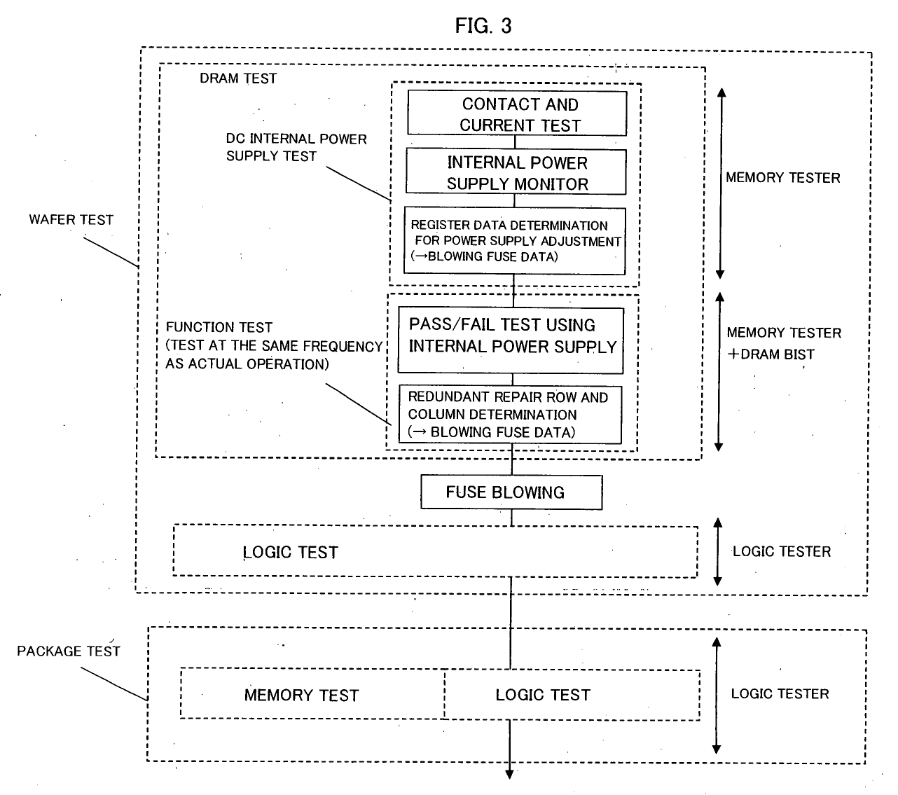

A test method using the semiconductor memory device which is composed as described above will be described using a test flow chart of the semiconductor memory device according to the first embodiment of the present invention shown in FIG. 3. As tests of the semiconductor memory device, a wafer test and a package test are performed in the order. As the wafer test, fuse blowing is performed after a DRAM test is performed, and a logic test is subsequently performed. As the DRAM test, a DC internal power supply test and a function test (test at the same frequency as that of an actual operation) are performed in the order. The DC internal power supply test is performed using the memory tester 2101, while the function test is performed using the memory tester 2101 and the DRAM BIST 17.

The logic test in the wafer test is performed using a logic tester. Meanwhile, the memory test and the logic test in the package test are performed using the logic tester.

First, before performing the function test in a wafer state, a voltage that is generated from the internal voltage power supply in a DC state is to be monitored by the memory tester 2101. When the monitored voltage is shifted from a target voltage due to process variability or the like, blowing information on the fuses 14a and 14b for power supply level adjustment is extracted according to a predetermined table. It should be noted that a contact and current test is to be performed before monitoring the internal power supply voltage.

Next, based on the blowing information on the aforementioned fuses 14a and 14, data of the registers 15a and 15b are set so that the same data as the data inputted upon fuse blowing into the aforementioned reference voltage generating circuits 13a and 13b may be outputted from the aforementioned registers 15a and 15b. Here, different internal voltages can be generated by setting different register data to respective DRAM macros. As a result, by using the internal voltage power supply of the internal power supply output level after blowing the fuses 14a and 14b for power supply adjustment, the function test (pass/fail test) that will be succeedingly performed can be executed.

It should be noted that, by using the aforementioned DRAM BIST 17, this function test could be performed on the condition of the same speed as that of an actual operation. The test pattern is sent to the memory control circuits 2104a and 2104b from the sequencer portion 18 of the DRAM BIST 17, and read data is thereby returned to the read result-determining portions 19a and 19b of the DRAM BIST 17. Pass/fail information (pass/fail data) during the function test is then sent to the memory tester 2101. Based on the pass/fail information (pass/fail data) during the function test, a redundant relief determination is made by the memory tester 2101 to determine a redundant relief row and column, so that redundant relief fuse information (blowing fuse data) will be extracted. After the completion of the function test, fuses for internal power supply adjustment and fuses for redundant relief are collectively blown using a trimming apparatus, so that a package inspection will finally be performed.

Consequently, by employing the configuration according to the embodiment of the present invention, during a function test (redundant relief) and during an actual operation, AC characteristics of loads that the internal power supplies drive are completely the same, and the driving power supplies are also the same, thereby making it possible to set response characteristics of the power supplies themselves to be completely the same, as well. For this reason, the internal power supply voltage levels supplied to DRAM cores during a function test and during an actual operation become completely the same. As a result, by correctly detecting a marginal bit that is sensitive to a voltage fluctuation to thereby perform the redundant relief thereto, an operation margin can be improved. Moreover, by simultaneously testing or activating a plurality of DRAM macros, the redundant relief determination can be made under the conditions where a noise that wrap-arounds from the power supply line and ground line is the most severe.

While a case where the number of DRAM macros is two is shown here, it may be equal to, more than or less than two. In addition, while the fuse, the register, the selector, and the reference voltage generating circuit are arranged in the respective DRAM macros, they may be arranged out of the DRAM macros. Further, while the voltage control data is supplied to the selectors 16a and 16b via the registers 15a and 15b, they may be directly supplied to the selectors 16a and 16b. Still further, the voltage control data may be inputted from an external terminal, or may be inputted from the DRAM BIST 17.

### Second Embodiment

Hereafter, referring to the drawings, a second embodiment of the present invention will be described.

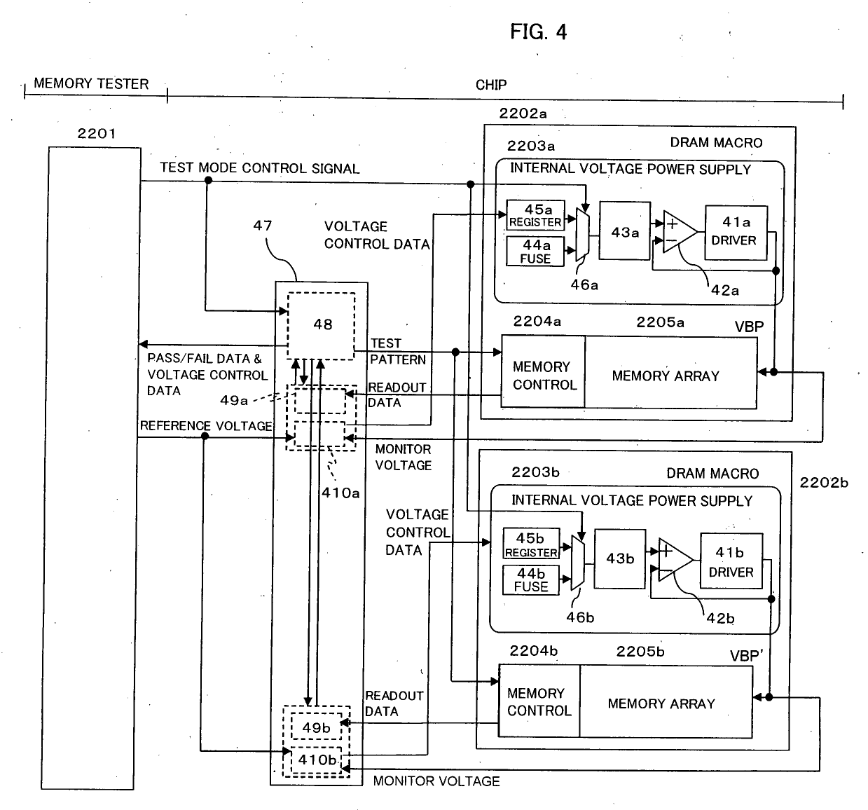

FIG. 4 shows a circuit configuration of a semiconductor memory device according to the second embodiment of the present invention. In FIG. 4, reference numeral 2201 represents a memory tester; reference numerals 2202a and 2202b, DRAM macros; reference numerals 2203a. and 2203b, internal voltage power supplies; reference numerals 2204a and 2204b, memory control circuits; and reference numerals 2205a and 2205b, memory arrays. Reference numerals 41a and 41b represent drivers; reference numerals 42a and 42b, amplifiers; reference numerals 43a and 43b, reference voltage generating circuits; reference numerals 44a and 44b, fuses which are non-volatile reference voltage memory means; reference numerals 45a and 45b, registers which are volatile reference voltage memory means; reference numerals 46a and 46b, selectors; reference numeral 47, a DRAM BIST; reference numeral 48, a sequencer portion; reference numerals 49a and 49b, read result-determining portions; and reference numerals 410a and 410b, voltage-tuning portions.

The voltage-tuning portions 410a and 410b are composed of a voltage tuning circuit described in, for example Japanese Unexamined Patent Publication (Kokai) No. 2001-35199. These voltage-tuning portions 410a and 410b provide voltage control data to the registers 45a and 45b, and change that value successively. In addition, internal voltages applied to the memory arrays 2205a and 2205b are inputted as monitor voltages, respectively. A reference voltage is also provided thereto from the outside (the memory tester 2201). Hence, the voltage-tuning portions 410a and 410b can set data stored in the aforementioned registers 45a and 45b to the DRAM macros 2202a and 2202b, respectively, so that a reference voltage provided from the external source (the memory tester 2201) and an internally generated voltage (monitor voltage) may be the same. Since other configurations are the same as those shown in FIG. 1, detailed description thereof will be omitted.

It should be noted that the read result-determining portion and the voltage-tuning portion are independently provided in each of the DRAM macros 2202a and 2202b. The broken line surrounding the read result-determining portion and the voltage-tuning portion indicates this.

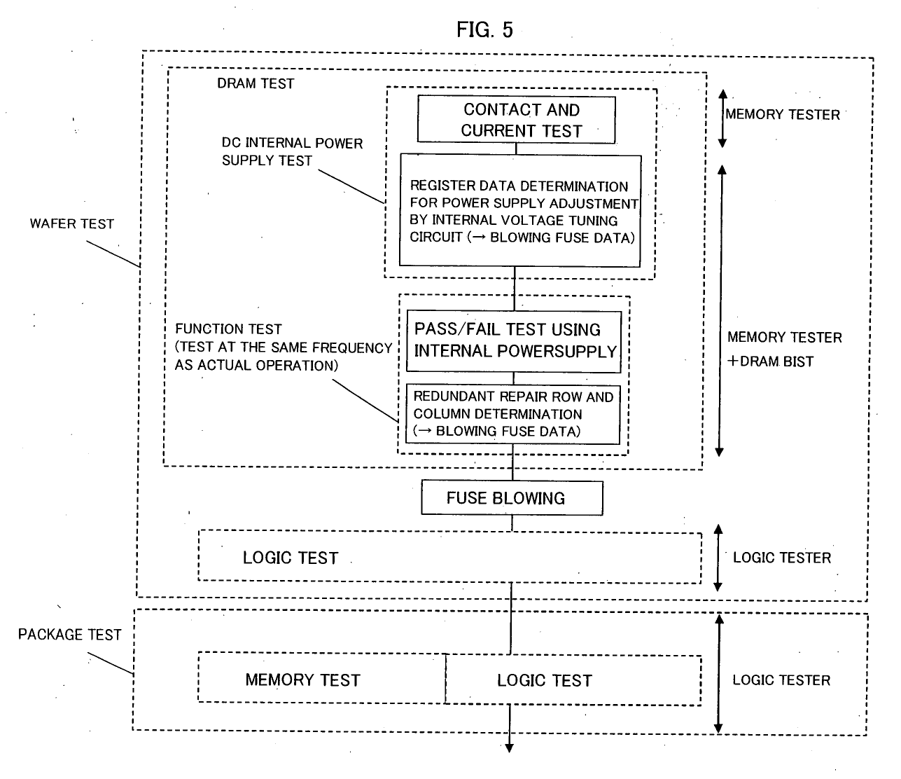

Next, a test flow chart shown in FIG. 5 will be described. As tests of the semiconductor memory device, a wafer test and a package test are performed in the order. As the wafer test, fuse blowing is performed after a DRAM test is performed, and a logic test is subsequently performed. As the DRAM test, a DC internal power supply test and a function test (test at the same frequency as that of an actual operation) are performed in the order. Among the DC internal power supply tests, a contact and current test is performed using the memory tester 2201, and a register data determination for power supply adjustment by the internal voltage tuning circuit is made using the memory tester 2201 and the DRAM BIST 47. The function test is performed using the memory tester 2201 and the DRAM BIST 47.

The logic test in the wafer test is performed using a logic tester. Meanwhile, the memory test and the logic test in the package test are performed using the logic tester.

By operating the voltage-tuning portions 410a and 410b during the DC internal power supply test before the function test, all of the DRAM macros can be set to the same voltage as a reference voltage that is applied from the external source. The register data determined by the aforementioned voltage-tuning portions 410a and 410b become the same as that of fuse blowing data for power supply adjustment. Since other flows are the same as those of FIG. 3, detailed description will be omitted.

According to the configuration in which the voltage-tuning portions 410a and 410b for tuning the internal voltages are built in such the DRAM BIST 47, even when the number of built-in DRAM macros is increased, the same or different data can be written into the aforementioned registers 45a and 45b, without being rate-controlled by the number of DC voltage monitor channels of the memory tester 2201. Moreover, as a result of this, all of the internal power supply voltages of a plurality of DRAM macros can easily be set to the same voltage, and a highly accurate redundant relief determination can also be made.

Needless to say, while the voltage-tuning portion is provided for every DRAM macro here, it may be provided in common to a plurality of DRAM macros. In addition, while the reference voltage is in common to all of DRAM macros, the reference voltage may also be individually supplied to each of the DRAM macros.

### Third Embodiment

Hereafter, referring to the drawings, a third embodiment of the present invention will be described.

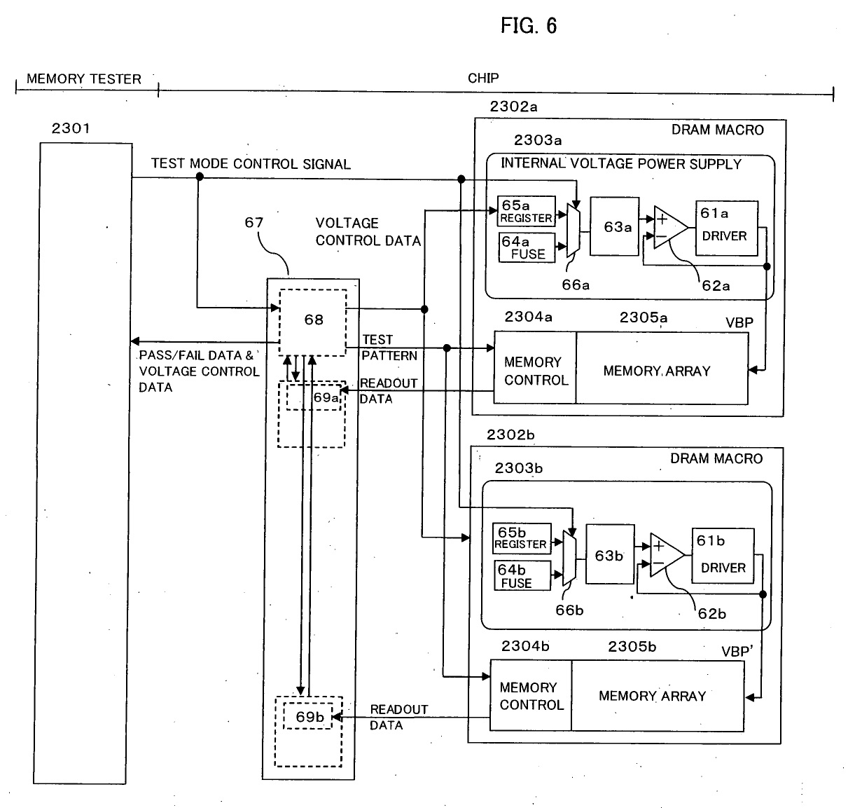

FIG. 6 shows a circuit configuration of a semiconductor memory device according to the third embodiment of the present invention. In FIG. 6, reference numeral 2301 represents a memory tester; reference numerals 2302a and 2302b, DRAM macros; reference numerals 2303a and 2303b, internal voltage power supplies; reference numerals 2304a and 2304b, memory control circuits; and reference numerals 2305a and 2305b, memory arrays. Reference numerals 61a and 61b represent drivers; reference numeral 62a and 62b, amplifiers; reference numerals 63a and 63b, reference voltage generating circuits; reference numerals 64a and 64b, fuses which are non-volatile reference voltage memory means; reference numerals 65a and 65b, registers; reference numerals 66a and 66b, selectors; reference numeral 67, a DRAM BIST; reference numeral 68, a sequencer portion; and reference numerals 69a and 69b, read result-determining portions.

This configuration is provided by removing the voltage monitor terminal from the configuration shown in FIG. 1, and is a configuration in which the voltage control data is inputted to the respective macros from the DRAM BIST 67. Since other configurations are the same as those of FIG. 1, detailed description will be omitted.

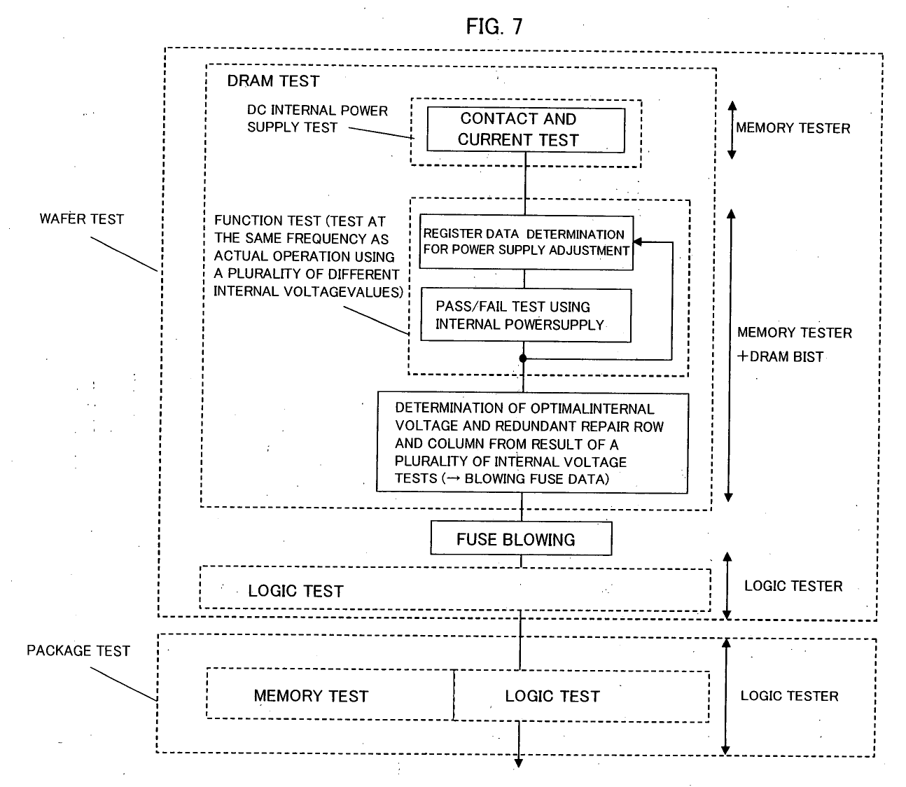

Next, a test flow chart shown in FIG. 7 will be described. As tests of the semiconductor memory device, a wafer test and a package test are performed in the order. As the wafer test, fuse blowing is performed after a DRAM test is performed, and a logic test is subsequently performed. As the DRAM test, after a DC internal power supply test and a function test (test at the same frequency as that of an actual operation) are performed in the order, an optimal internal voltage and a redundant relief row and column are determined from the result of function tests at a plurality of internal voltage to thereby determine blowing fuse data. A contact and current test which is the DC internal power supply test is performed using the memory tester 2301, and the function test is performed using the memory tester 2301 and the DRAM BIST 67.

The logic test in the wafer test is performed using a logic tester. Meanwhile, a memory test and a logic test in the package test are performed using the logic tester.

In FIG. 7, there is shown a flow in which the internal voltage level is not set to the predetermined target voltage based on the result of the voltage monitor, but a plurality of function (redundant relief determination) tests are actually performed at different internal voltage levels to thereby select the optimal internal voltage level. As a certain method of determining the optimal internal voltage level, there is a method of setting an internal voltage value having fewer fails than any other internal voltage values to the optimal voltage value based on the result of the function test.

By employing the configuration according to the third embodiment of the present invention, in a manner similar to the aforementioned first embodiment, a redundant relief determination test that completely eliminates the error between the internal power supply voltages during a function test and during an actual operation can be performed. Moreover, it is possible to solve a problem that the initially determined target voltage itself of the internal power supply is not necessarily the optimal for each of chips, which is a primary problem in the test method from the past.

According to the third embodiment of the present invention, data values of the respective registers 65a and 65b for internal voltage adjustment, which have finally been able to achieve the largest operation margin to a plurality of DRAM macros, will be set to the respective blowing fuse data values. An optimal internal voltage setting which reflects an actual operation, and a highly accurate redundant relief determination at the internal voltage value can therefore be made individually for respective DRAM macros.

In addition, since the voltage monitor is not particularly required, even when the number of incorporated Dram macros is increased, channel rate controlling of the memory tester may not be caused.

Moreover, if the same voltage setting data is provided to the registers 65a and 65b for voltage adjustment of all DRAM macros to thereby perform a plurality of tests, the voltage control data is easily controlled from the DRAM BIST 67.

Needless to say, the aforementioned test method may be applied to the configuration provided with the voltage monitor terminal, or the configuration in which the voltage control data is controlled from the memory tester.

### Fourth Embodiment

Hereafter, referring to the drawings, a fourth embodiment of the present invention will be described.

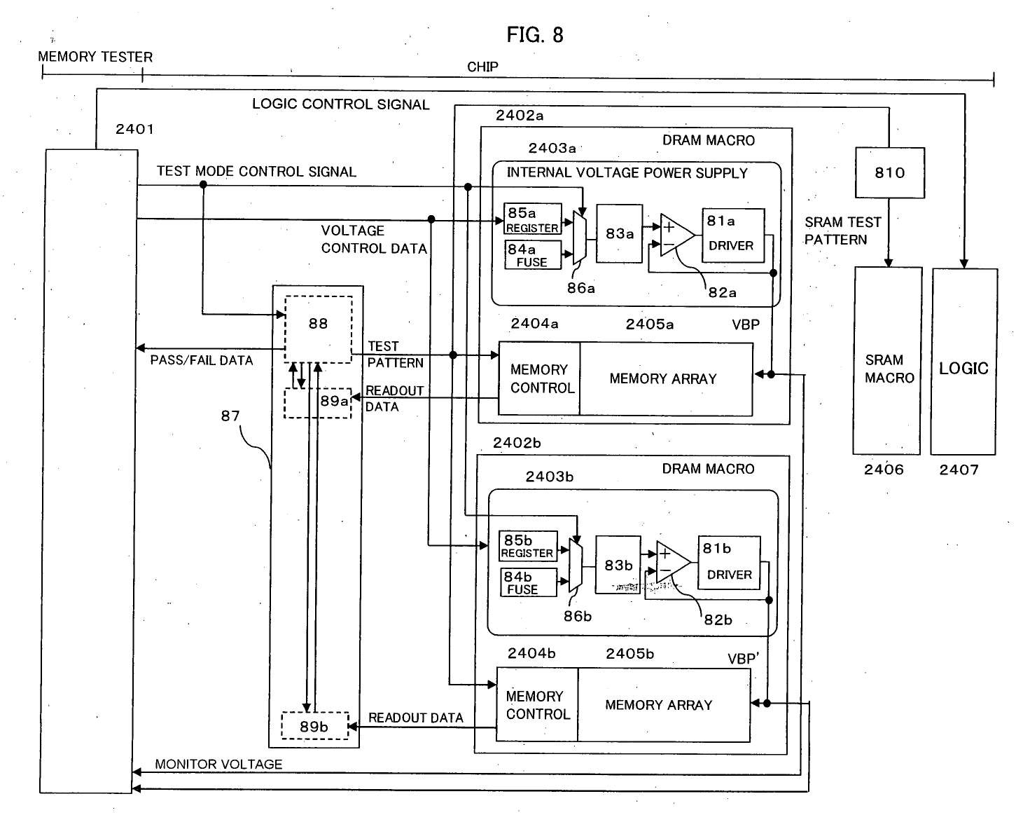

FIG. 8 shows a circuit configuration of a semiconductor memory device according to the fourth embodiment of the present invention. In FIG. 8, reference numeral 2401 represents a memory tester; reference numerals 2402a and 2402b, DRAM macros; reference numerals 2403a and 2403b, internal voltage power supplies; reference numerals 2404a and 2404b, memory control circuits; reference numeral 2405a and 2405b, memory arrays; reference numeral 2406, an SRAM macro; and reference numeral 2407, a logic circuit. Reference numerals 81a and 81b represent drivers; reference numerals 82a and 82b, amplifiers; reference numerals 83a and 83b, reference voltage generating circuits; reference numerals 84a and 84b, fuses which are non-volatile reference voltage memory means; reference numerals 85a and 85b, registers which are volatile reference voltage memory means; reference numerals 86a and 86b, selectors; reference numeral 87, a DRAM BIST; reference numeral 88, a sequencer portion; reference numerals 89a and 89b, read result-determining portions; and reference numeral 810, a SRAM BIST (or SRAM BISR (Built In Self Repair)).

This configuration shows a configuration in which the SRAM macro 2406, and the SRAM BIST 810 and the logic circuit 2407 for testing it, which are formed on the same semiconductor substrate using SOC are added to the configuration shown in FIG. 1, and the aforementioned SRAM BIST 810 is controlled by the DRAM BIST 87.

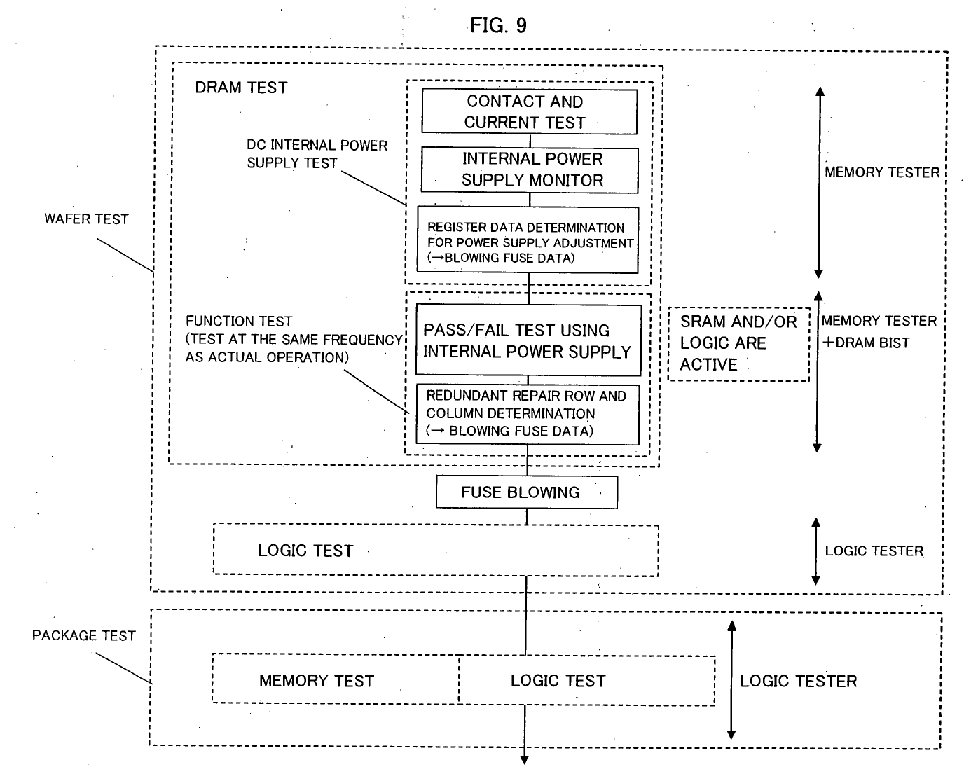

Next, a test flow chart shown in FIG. 9 will be described. As tests of the semiconductor memory device, a wafer test and a package test are performed in the order. As the wafer test, fuse blowing is performed after a DRAM test is performed, and a logic test is subsequently performed. As the DRAM test, a DC internal power supply test and a function test (test at the same frequency as that of an actual operation) are performed in the order. The DC internal power supply test is performed using the memory tester 2401, and the function test is performed using the memory tester 2401 and the DRAM BIST 87. During the function test, the SRAM macro 2406 and/or the logic circuit 2407 become active.

The logic test in the wafer test is performed using a logic tester. Meanwhile, a memory test and a logic test in the package test are performed using the logic tester.

As shown in FIG. 9, during the function test of the DRAM macros 2402a and 2402b, the SRAM macro 2406 can be activated or tested via the SRAM BIST 810 by the control signal from the DRAM BIST 87. Meanwhile, the logic circuit 2407 can also be activated (a certain scan test pattern is executed) by a logic control signal from the memory tester 2401 at the same time.

By employing the configuration according to the embodiment of the present invention, it is possible to make a highly accurate redundant relief determination of a marginal bit in reproducing the noise normally through the power supply line and the ground line during an SOC chip operation. Particularly, when all of the SRAM macros and logic circuits are simultaneously activated, it is possible to make a redundant relief determination of a marginal bit in reproducing the worst condition of the noise through the power supply line and the ground line during an actual SOC operation. Moreover, by testing the SRAM itself during activating the SRAM, it is also possible to achieve a reduction in test time.

Needless to say, the SRAM BIST 810 may be the SRAM BISR. In addition, while there is shown the configuration in which the SRAM BIST is controlled by the DRAM BIST here, a configuration in which the SRAM BIST is directly controlled from the tester may also provide the similar effect.

### Fifth Embodiment

Hereafter, referring to the drawings, a fifth embodiment of the present invention will be described.

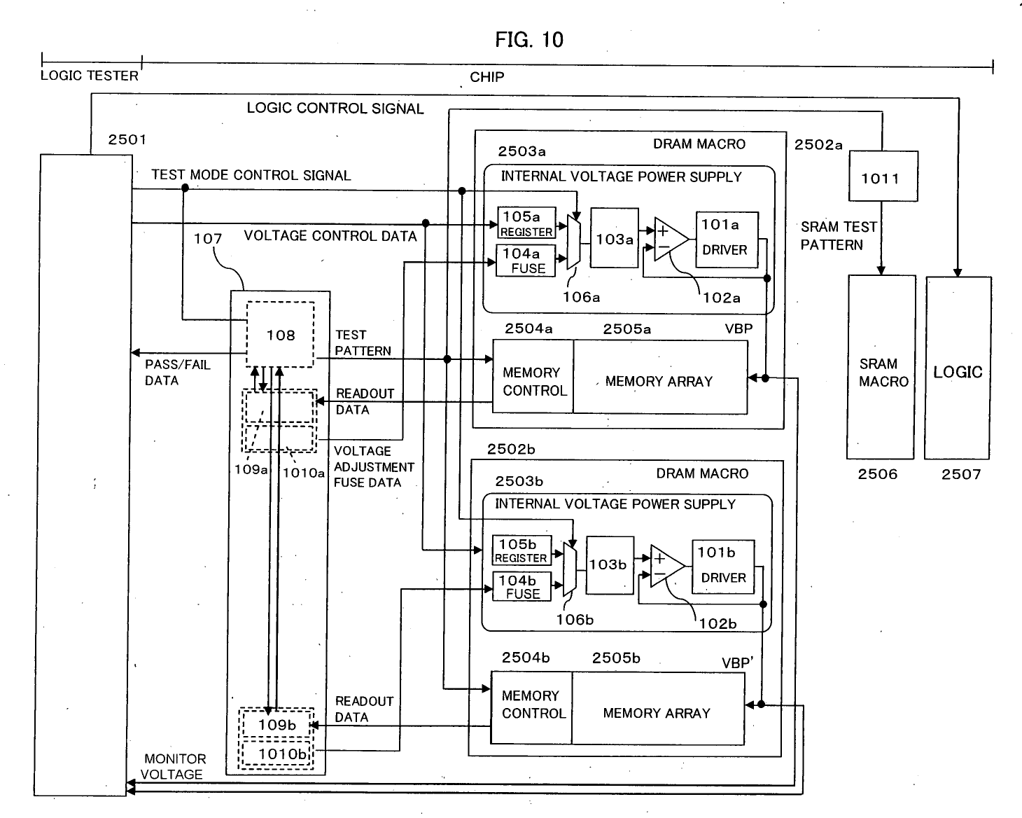

FIG. 10 shows a circuit configuration of a semiconductor memory device according to the fifth embodiment of the present invention. In FIG. 10, reference numeral 2501 represents a logic tester; reference numerals 2502a and 2502b, DRAM macros; reference numerals 2503a and 2503b, internal voltage power supplies; reference numerals 2504a and 2504b, memory control circuits; reference numeral 2505a and 2505b, memory arrays; reference numeral 2506, an SRAM macro; and reference numeral 2507, a logic circuit. Reference numerals 101a and 101b represent drivers; reference numeral 102a and 102b, amplifiers; reference numerals 103a and 103b, reference voltage generating circuits; reference numerals 104a and 104b, fuses which are non-volatile reference voltage memory means; reference numerals 105a and 105b, registers which are volatile reference voltage memory means; reference numerals 106a and 106b, selectors; reference numeral 107, a DRAM BISR, reference numeral 108, a sequencer portion; reference numeral 109a and 109b, read result-determining portions; reference numerals 1010a and 1010b, registers for voltage adjustment fuses which store voltage adjustment fuse data; and reference numeral 1011, an SRAM BIST (or SRAM BISR).

According to a configuration shown in FIG. 10, the DRAM BIST 87 in the configuration shown in FIG. 8 is replaced with the DRAM BISR 107. In other words, it results in a built-in test circuit provided with redundant relief determination means which is not shown. In addition, the aforementioned DRAM BISR 107 is also provided with the registers 1010a and 1010b which store the blowing fuse data for power supply adjustment, and the DRAM is further provided with the BISR, so that it is configured in such a way that the DRAM test is performed by the logic tester 2501. It is also configured so that a typical electrical fuse may be used as the fuses 104a and 104b for voltage adjustment.

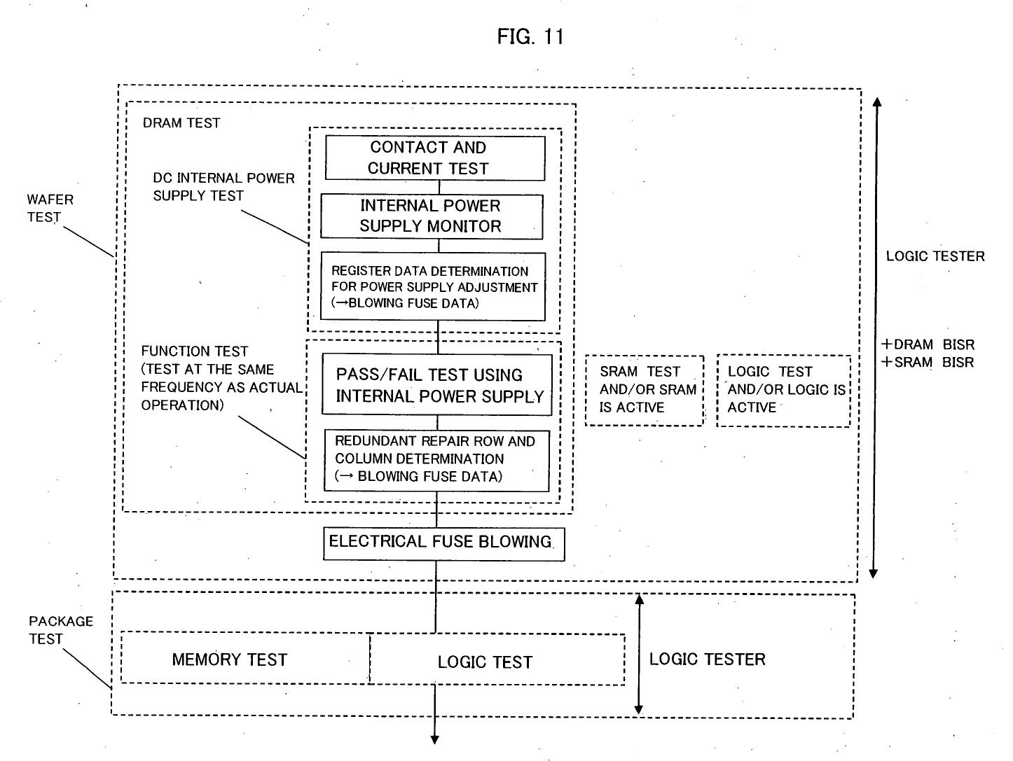

Next, a test flow chart shown in FIG. 11 will be described. As tests of the semiconductor memory device, a wafer test and a package test are performed in the order. As the wafer test, after a DRAM test is performed, fuse blowing is performed. As the DRAM test, a DC internal power supply test and a function test (test at the same frequency as that of an actual operation) are performed in the order. The wafer test is performed using the logic tester 2501, the DRAM BISR 107, and the SRAM BISR. During the function test, a test is performed to the SRAM macro 2506, and/or the SRAM macro 2506 becomes active. At this time, a logic test is also performed, and/or the logic circuit 2507 becomes active.

Meanwhile, a memory test and a logic test in the package test are performed using the logic tester.

As shown in FIG. 11, during the function test of the DRAM, the SRAM macro 2506 can be activated or tested via the SRAM BIST 1011 by a control signal from DRAM BISR 107. Meanwhile, the logic circuit 2507 may also be activated or tested by a logic control signal from the logic tester 2501 at the same time.

By employing the configuration according to the embodiment of the present invention, all of the DRAM macros 2502a and 2502b, the SRAM macro 2506, and the logic circuit 2507 can be tested in parallel using the logic tester 2501, and it is also possible to make a redundant relief determination of a marginal bit of the DRAM macro in reproducing the worst condition of the noise through the power supply line and the ground line during the actual SOC operation. Moreover, by using the electrical fuse for the fuses 104a and 104b for voltage adjustment, and also using the data of the registers 110a and 110b for voltage adjustment fuse that are built in the DRAM BISR 107, the fuse can be blown without using a dedicated trimming apparatus (namely, using the logic tester 2501). A reduction in test man-hour and test time can therefore be achieved while improving redundant relief accuracy.

### Sixth Embodiment

Hereinafter, a sixth embodiment of the present invention will be described.

The sixth embodiment of the present invention is a method of highly accurately setting the DRAM internal power supply, which is particularly possible only when the aforementioned non-volatile reference voltage memory means is the electrical fuse.

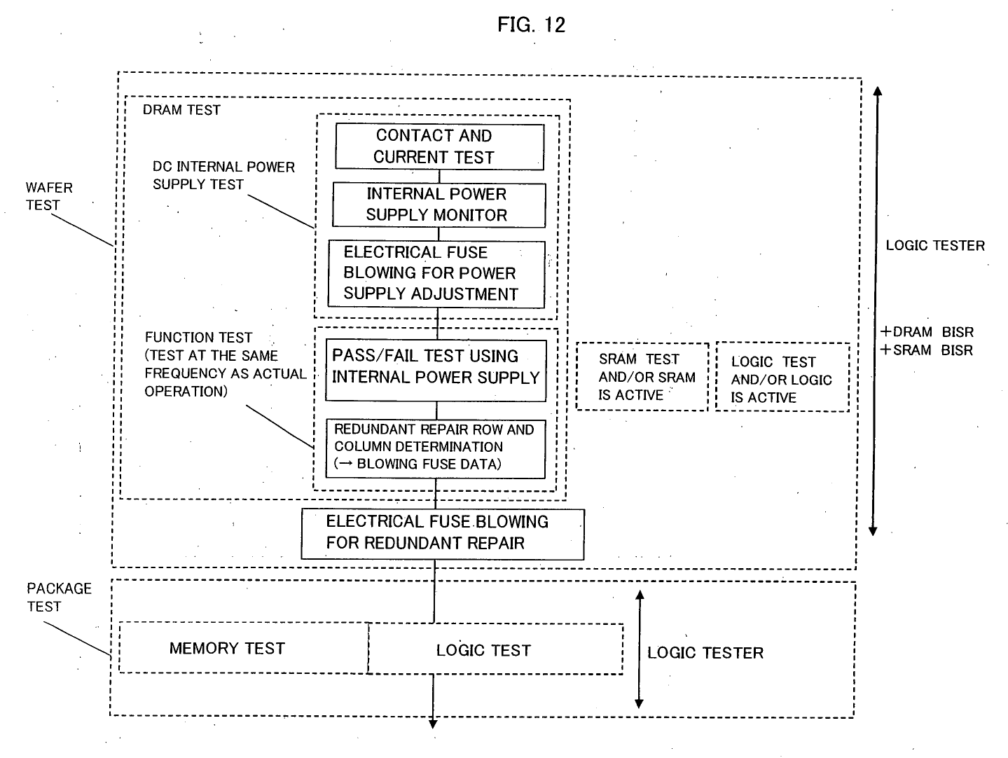

A test flow chart shown in FIG. 12 will be described as described in the aforementioned fifth embodiment of the present invention, by using the electrical fuse, fuse blowing itself can be performed on the logic tester. In this case, the fuse for power supply adjustment is blown based on a result of a DC internal voltage monitor, and a function (redundant relief determination) test is then performed in the state where the internal voltage output is set to a value after the adjustment, so that a highly accurate redundant repair determination can be made. Subsequently, the electrical fuse for redundant relief is blown.

At this time, in order to separately blow the fuse for power supply adjustment and the fuse for redundant relief, since the fuse trimming apparatus has conventionally been required to be used twice, an overhead for test man-hour has been high. According to the embodiment of the present invention, however, since all of the test and fuse blowing can be performed on the logic tester, such problem may not be generated. Moreover, in the present embodiment, since the aforementioned volatile reference voltage memory means is not necessarily required in particular, a reduction in chip area can also be achieved.

In the first through sixth embodiments of the invention described above, while the internal voltage power supply for generating the bit line precharge voltage VBP has been described as the examples, needless to say, a similar configuration and test method may also be used to an internal voltage power supply for generating a cell plate voltage VCP, a substrate voltage VBB, a DRAM main voltage VDD, and a word line boot voltage VPP.

### Seventh Embodiment

Hereinafter, a seventh embodiment of the present invention will be described.

The seventh embodiment of the present invention is a form in which the method of highly accurately setting the DRAM internal power supply, which has been described above, is similarly applied to the internal power supply of the SRAM. At present, although the SRAM is not usually provided with the internal power supply, an increase in leakage current and a decrease in static noise margin have been a problem with future microfabrication, and in order to solve these problems, for example, a power supply for substrate bias of an array portion, and a power supply for word line and bit line boot may be used as the internal power supply.

By employing the configuration according to the embodiment of the present invention, the internal power supply voltages of these SRAMs can be set accurately, and a redundant relief of a marginal bit can be performed highly accurately.

It should be considered that the embodiments disclosed here are intended to be exemplary only at all points, but not to be restrictive, and it cannot be overemphasized that various modifications can be made within the scope of the technical thought of the present invention.

### INDUSTRIAL APPLICABILITY

A semiconductor memory device and a test method thereof in accordance with the present invention are useful as a method of achieving a highly accurate redundant relief determination by using an internal power supply and by making a redundant relief determination at the same speed as that of an actual operation, and achieving an improvement in memory operation margin resulting from an improvement in internal power supply voltage setting accuracy and an improvement in redundant relief accuracy in not only a DRAM, but also an SRAM and other memories having the internal power supply.

What is claimed is:

1. A semiconductor integrated circuit, comprising:
at least one dynamic RAM comprising a first memory cell array composed of a plurality of memory cells, and a first internal voltage generating circuit for generating a first internal voltage based on a reference voltage;
first non-volatile reference voltage memory means for non-volatilely storing a first reference voltage setting data which sets a reference voltage of said at least one dynamic RAM, and outputting said first reference voltage setting data;
first volatile reference voltage memory means for volatilely storing a second reference voltage setting data which sets a reference voltage of said at least one dynamic RAM, and outputting said second reference voltage setting data;
a first selector for selecting and outputting either of an output of said first non-volatile reference voltage memory means, and an output of said first volatile reference voltage memory means;
first reference voltage generating means for generating a reference voltage of said at least one dynamic RAM based on an output of said first selector to input it to said first internal voltage generating circuit; and
first built-in memory test means comprising a sequencer portion for generating a test signal including a write/read address and a write-in data, and at least one result-determining portions for determining a test result by comparing the test signal from said sequencer portion with data contents read from said at least one dynamic RAM.

2. The semiconductor integrated circuit according to claim 1, wherein said first built-in memory test means comprises voltage tuning means for individually changing a value of said second reference voltage setting data to be written in said first volatile reference voltage memory means in said at least one dynamic RAM to thereby tune so that a reference voltage supplied from an external terminal and said first internal voltage may be the same voltage, respectively.

3. The semiconductor integrated circuit according to claim 1, wherein said first built-in memory test means comprises memory means for said second reference voltage setting data to be written in said first non-volatile reference voltage memory means, and redundant relief determination means for said at least one dynamic RAM.

4. The semiconductor integrated circuit according to claim 1, wherein said first non-volatile reference voltage memory means is an electrical fuse.

5. The semiconductor integrated circuit according to claim 1, wherein said first internal voltage is any of a bit line precharge voltage, a cell plate voltage, a substrate bias voltage of said first memory cell array, a main power supply voltage of said at least one dynamic RAM, and a word line voltage.

6. The semiconductor integrated circuit according to claim 1, further comprising: at least one static RAM; second built-in memory test means for testing said at least one static RAM; and a logic circuit.

7. The semiconductor integrated circuit according to claim 6, wherein said second built-in memory test means is controlled by an output signal from said first built-in memory test means to thereby activate said at least one static RAM.

8. The semiconductor integrated circuit according to claim 6, wherein said at least one static RAM comprises a second memory cell array composed of a plurality of memory cells, and a second internal voltage generating circuit for generating a second internal voltage based on a reference voltage,
the semiconductor integrated circuit further comprising: second non-volatile reference voltage memory means for non-volatilely storing a third reference voltage setting data which sets a reference voltage of said at least one static RAM, and outputting said third reference voltage setting data; second volatile reference voltage memory means for volatilely storing a fourth reference voltage setting data which sets a reference voltage of said at least one static RAM, and outputting said fourth reference voltage setting data; a second selector for selecting and outputting either of an output of said second non-volatile reference voltage memory means, and an output of said second volatile reference voltage memory means or said second voltage control means; and second reference voltage generating means for generating a reference voltage of said at least one static RAM based on an output of said second selector to input it to said second internal voltage generating circuit.

9. The semiconductor integrated circuit according to claim 8, wherein said second internal voltage is a substrate bias voltage, or a power supply voltage of a word line or a bit line of the second memory cell array.

10. A test method of the semiconductor integrated circuit that is described in claim 1, wherein a function test of the dynamic RAM is performed at said first internal voltage generated based on said second reference voltage data which is volatilely stored in said first volatile reference voltage memory means, and at the same operating speed as that of an actual chip.

11. The test method of the semiconductor integrated circuit according to claim 10, wherein said at least one dynamic RAM includes a plurality of dynamic RAMs, and said function test of said plurality of dynamic RAMs is performed in a state where all of said plurality of dynamic RAMs are activated.

12. The test method of the semiconductor integrated circuit according to claim 10, wherein said second reference voltage setting data written in said first volatile reference voltage memory means during said function test, and said second reference voltage setting data written in said first non-volatile reference voltage memory means after said function test are the same.

13. The test method of the semiconductor integrated circuit according to claim 10, wherein by writing a plurality of different second reference voltage setting data in said first volatile reference voltage memory means, said function test is performed at a plurality of first internal voltage levels, and after said function test, any second reference voltage setting data among said plurality of different second reference voltage setting data is written in said non-volatile memory means as said first reference voltage setting data.

14. The test method of the semiconductor integrated circuit according to claim 10, wherein said first internal voltage is any of a bit line precharge voltage, a cell plate voltage, a substrate bias voltage of said first memory cell array, a main power supply voltage of said at least one dynamic RAM, and a word line voltage.

15. A test method of the semiconductor integrated circuit that is described in claim 6, wherein said at least one static RAM includes a plurality of static RAMs, and a function test of the dynamic RAM is performed in a state where all of said plurality of static RAMs are activated, a state where said logic circuit is activated, or a state where said plurality of static RAMs and said logic circuit are simultaneously activated.

16. A semiconductor integrated circuit, comprising:
at least one dynamic RAM comprising a first memory cell array composed of a plurality of memory cells, and a first internal voltage generating circuit for generating a first internal voltage based on a reference voltage;
a first electrical fuse for non-volatilely storing first reference voltage setting data which sets a reference voltage of said at least one dynamic RAM, and outputting said first reference voltage setting data;
first reference voltage generating means for generating a reference voltage of said at least one dynamic RAM based on an output of said electrical fuse to input it to said first internal voltage generating circuit; and
first built-in memory test means comprising a sequencer portion for generating a test signal including a write/read address and a write-in data, and at least one result-determining portions for determining a test result by comparing the test signal from said sequencer portion with data contents read from said at least one dynamic RAM.

17. The semiconductor integrated circuit according to claim 16, wherein said first internal voltage is any of a bit line precharge voltage, a cell plate voltage, a substrate bias voltage of said first memory cell array, a main power supply voltage of said at least one dynamic RAM, and a word line voltage.

18. The semiconductor integrated circuit according to claim 16, further comprising: at least one static RAM; second built-in memory test means for testing said at least one static RAM; and a logic circuit.

19. The semiconductor integrated circuit according to claim 18, wherein said second built-in memory test means is controlled by an output signal from said first built-in memory test means to thereby activate said at least one static RAM.

20. The semiconductor integrated circuit according to claim 18, wherein said at least one static RAM comprises a second memory cell array composed of a plurality of memory cells, and a second internal voltage generating circuit for generating a second internal voltage based on a reference voltage,
the semiconductor integrated circuit further comprising: a second electrical fuse for non-volatilely storing second reference voltage setting data which sets a reference voltage of said at least one static RAM, and outputting said second reference voltage setting data; and second reference voltage generating means for generating a reference voltage of said at least one static RAM based on an output of said second electrical fuse to input it to said second internal voltage generating circuit.

21. The semiconductor integrated circuit according to claim 20, wherein said second internal voltage is a substrate bias voltage, or a power supply voltage of a word line or a bit line of the second memory cell array.

22. A test method of the semiconductor integrated circuit that is described in claim 16, wherein after blowing an electrical fuse for non-volatilely storing said reference voltage setting data, a redundant relief determination test is performed.

23. The semiconductor integrated circuit according to claim 22, wherein said first internal voltage is any of a bit line precharge voltage, a cell plate voltage, a substrate bias voltage of said first memory cell array, a main power supply voltage of said at least one dynamic RAM, and a word line voltage.

24. A test method of the semiconductor integrated circuit that is described in claim 18, wherein said at least one static RAM includes a plurality of static RAMs, and a function test of the dynamic RAM is performed in a state where all of said plurality of static RAMs are activated, a state where said logic circuit is activated, or a state where said plurality of static RAMs and said logic circuit are simultaneously activated.

25. A semiconductor integrated circuit, comprising:
at least one dynamic RAM comprising a first memory cell array composed of a plurality of memory cells, and a first internal voltage generating circuit for generating a first internal voltage based on a reference voltage;
first non-volatile reference voltage memory means for non-volatilely storing a first reference voltage setting data which sets a reference voltage of said at least one dynamic RAM, and outputting said first reference voltage setting data;
an external terminal which is connected to first voltage control means for outputting a second reference voltage setting data which sets a reference voltage of said at least one dynamic RAM, and to which said second reference voltage setting data is inputted;
a first selector for selecting and outputting either of an output of said first non-volatile reference voltage memory means, and an input from said external terminal;
first reference voltage generating means for generating a reference voltage of said at least one dynamic RAM based on an output of said first selector to input it to said first internal voltage generating circuit; and
first built-in memory test means comprising a sequencer portion for generating a test signal including a write/read address and a write-in data, and at least one result-determining portions for determining a test result by comparing the test signal from said sequencer portion with data contents read from said at least one dynamic RAM.

26. A test method of the semiconductor integrated circuit that is described in claim 25, wherein a function test of the dynamic RAM is performed at a first internal voltage generated based on said second reference voltage setting data which is inputted from said external terminal, and at the same operating speed as that of an actual chip..
